(19) United States
(12) Patent Application Publication
(10) Pub. No.: US 2021/0165236 A1
(43) Pub. Date: Jun. 3, 2021

(54) ACOUSTICALLY COUPLED VIBRATION OF AN OPTICAL COMPONENT FOR REDUCING LASER COHERENCE EFFECTS INCLUDING SPECKLE

(71) Applicant: CORNING INCORPORATED, Corning, NY (US)

(72) Inventors: Stephen Karl Mack, Rush, NY (US); Matthew Ronald Millecchia, Fairport, NY (US)

(21) Appl. No.: 16/953,527

(22) Filed: Nov. 20, 2020

Related U.S. Application Data
(60) Provisional application No. 62/942,939, filed on Dec. 3, 2019.

(51) Int. Cl. G02B 27/48; H01S 3/106; G01B 9/02

(52) U.S. Cl. CPC G02B 27/48; G01B 9/02082; H01S 3/106

(57) ABSTRACT

Systems and methods for reducing laser coherence effect within an optical system are disclosed. A system includes an acoustic device, a signal generator electrically coupled to the acoustic device, where the signal generator generates an electrical signal comprising a predefined frequency and a predefined amplitude for output by the acoustic device, and an optical system comprising a laser light source configured to produce a beam where one or more optical elements are disposed along the beam path that impinges or propagates through the one or more optical elements. The acoustic device is positioned at a distance from the one or more optical elements such that an acoustic signal emitted by the acoustic device causes one or more optical elements to vibrate such that laser coherence effects of the beam are reduced.

This Application claims priority under 35 USC § 119(e) from U.S. Provisional Patent Application Ser. No. 62/942,939, filed on Dec. 3, 2019 which is incorporated by reference herein in its entirety.

### TECHNICAL FIELD

The present disclosure generally relates to systems and methods for reducing laser coherence effects by acoustically vibrating an optical component, and more specifically, to systems and methods that reduce laser coherence effects by acoustically vibrating components in laser projection systems and interferometric measurement systems.

### BACKGROUND

Optical imaging applications, such as holography and interferometry, require highly coherent light for producing images. Speckle, which can degrade image quality, arises from the same phenomenon of interference that is exploited for purposes of image contrast. Any scattering of light within coherent imaging systems can produce local phase interactions resulting in seemingly random patterns of constructive and destructive interference that can obscure the desired interference patterns. Such scattering can arise from any number of sources including dust, imperfect imaging optics, and stray reflections, as well as from the subject object for imaging.

Diffuser surfaces have been used to mitigate speckle. By rotating the diffuser surfaces and exploiting the integration interval of image capturing devices (including the human eye) to average together the different resulting speckle patterns over time, speckle patterns have been reduced. Conventional speckle reduction systems focus the output beam of a laser onto a rotating diffuser plate. The diffuse focus on the plate forms a new spot source for the illumination system. The diameter of the diffuser plate at which the laser beam is focused and the rate at which the plate is rotated (together quantifiable as a local linear speed of the plate with respect to the focused beam) are adjusted so that speckle contrast is sufficiently reduced within the integration interval of a camera. Generally, speckle contrast is reduced by the square root of the number of uncorrelated speckle patterns within a given integration interval.

Rotating diffusers, particularly within precision optical devices, have some disadvantages, including the generation of heat and noisy vibrations. Ongoing demands for capturing images within shorter integration intervals of the cameras require the diffusers to be larger in diameter or rotated at higher speeds to maintain a desired amount of speckle reduction. The larger diffusers and higher speeds, as well as higher power motors, tend to increase undesirable heat and vibration, which can disturb desired imaging within the precision optical imaging devices.

Other speckle reduction systems appear to utilize mechanical means such as piezoelectric devices or a motor and cam configuration coupled to an optical element to cause the optical element to move in a predefined motion. For example, some devices move the optical element back-and-forth so that linear reciprocating motion may be carried out thereby changing the optical path.

However, it has been determined that systems and methods of direct mechanical movement of an optical element limits the ability to vibrate and tune an optical element in ways that further improve the reduction of laser coherence effects such as speckle and spurious fringes. Moreover, laser coherence effects may be caused by multiple optical elements and thus may be reduced by resonating the one or more optical elements. However, optical elements within a system may not be accessible for direct mechanical coupling due to their size, inability or difficulty to access, or sensitivity.

Accordingly, a need exists for systems and methods that implement a non-contact method configured to resonate (vibrate) one or more optical elements in an optical system to reduce laser coherence effects such as speckle or spurious fringes.

### SUMMARY

In a first aspect Al, a system includes an acoustic device, a signal generator electrically coupled to the acoustic device, wherein the signal generator generates an electrical signal comprising a predefined frequency and a predefined amplitude for output by the acoustic device, and an optical system comprising a laser light source configured to produce a beam wherein one or more optical elements are disposed along the beam path that impinges or propagates through the one or more optical elements. The acoustic device is positioned at a distance from the one or more optical elements such that an acoustic signal emitted by the acoustic device causes one or more optical elements to vibrate such that laser coherence effects of the beam are reduced.

A second aspect A2 includes the system A1, wherein the one or more elements include an optical element of the laser light source.

A third aspect A3 includes the system A1 or A2, wherein the predefined frequency is a resonant frequency of at least one of the one or more optical elements of the optical system.

A fourth aspect A4 includes the system of any of the first to third aspects A1-A3, wherein the predefined frequency is a frequency of from about 700 Hz to about 900 Hz.

A fifth aspect A5 includes the system of any of the first to fourth aspects A1-A4, wherein the optical system includes two or more optical elements and the acoustic signal emitted by the acoustic device causes at least two of the optical elements to vibrate.

A sixth aspect A6 includes the system of any of the first to fifth aspects A1-A5, further comprising: a detector positioned within the optical system along a beam path of the beam produced by the laser light source; a computing device communicatively coupled to the detector and the signal generator, wherein the computing device is programmed to: receive detector data from the detector while the acoustic device emits the acoustic signal corresponding to the electrical signal comprising the predefined frequency; determine whether laser coherence effects are present within the beam based on the detector data captured by the detector; in response to determining the presence of laser coherence effects, select a second predetermined frequency for generation by the signal generator, wherein the second predetermined frequency is different than the predetermined frequency, and cause the signal generator to generate an electrical signal comprising the second predetermined frequency such that the acoustic device emits a second acoustic signal corresponding to the electrical signal comprising the second predefined frequency.

A seventh aspect A7 includes the system A6, wherein the computing device is further programmed to: in response to determining the presence of laser coherence effects, select a second amplitude for generation by the signal generator, wherein the second amplitude is different than the amplitude; and cause the signal generator to generate an electrical signal comprising the second amplitude such that the acoustic device emits a third acoustic signal corresponding to the electrical signal comprising the second amplitude.

An eighth aspect A8 includes the system of any of the first to seventh aspects A1-A7, wherein the one or more optical elements of the optical system are configured within an enclosure and the acoustic generating device is positioned outside the enclosure.

A ninth aspect A9 includes the system of any of the first to eighth aspects A1-A8, wherein the one or more optical elements of the optical system are configured within an enclosure and the acoustic generating device is positioned within the enclosure.

A tenth aspect A10 includes the system of any of the first to ninth aspects A1-A9, wherein the optical system is an interferometric measurement system.

An eleventh aspect A11 includes the system of any of the first to ninth aspects A1-A9, wherein the optical system is a laser projection device.

A twelfth aspect A12 includes the system of any of the first to eleventh aspects A1-A11, wherein the acoustic device is positionable at a plurality of distances from the one or more optical elements of the optical system.

A thirteenth aspect A13 includes the system of any of the first to twelfth aspects A1-A12, wherein the one or more optical elements comprises at least one of a prism, a beam splitter, a lens, a mirror, a diffuser, a diffractive grating or optical fiber.

In a fourteenth aspect A14, a method includes generating an electrical signal, with a signal generator, comprising a predefined frequency and a predefined amplitude for output by an acoustic device electrically coupled to the signal generator, wherein the acoustic device is positioned a distance from an optical system comprising a laser light source configured to produce a beam wherein one or more optical elements are disposed along the beam path that impinges or propagates through the one or more optical elements, and emitting, with the acoustic device, an acoustic signal corresponding to the electrical signal received from the signal generator, wherein the acoustic signal causes one or more optical elements to vibrate such that laser coherence effects of the beam are reduced.

A fifteenth aspect A15 includes the method of the fourteenth aspect A14, wherein the one or more optical elements includes an optical element of the laser light source.

A sixteenth aspect A16 includes the method of any of the fourteenth to fifteenth aspects A14-A15, wherein the predefined frequency is a resonant frequency of at least one of the one or more optical elements of the optical system.

A seventeenth aspect A17 includes the method of any of the fourteenth to sixteenth aspects A14-A16, wherein the predefined frequency is a frequency of from about 700 Hz to about 900 Hz.

An eighteenth aspect A18 includes the method of any of the fourteenth to seventeenth aspects A14-A17, wherein the optical system includes two or more optical elements and the acoustic signal emitted by the acoustic device causes at least two of the optical elements to vibrate.

A nineteenth aspect A19 includes the method of any of the fourteenth to eighteenth aspects A14-A18, further comprising: receiving, at a computing device, detector data from a detector positioned within the optical system along a beam path of the beam produced by the laser light source, while the acoustic device emits the acoustic signal corresponding to the electrical signal comprising the predefined frequency; determining whether laser coherence effects are present within the beam based on the detector data captured by the detector; in response to determining the presence of laser coherence effects, selecting a second predetermined frequency for generation by the signal generator, wherein the second predetermined frequency is different than the predetermined frequency; and causing the signal generator to generate an electrical signal comprising the second predetermined frequency such that the acoustic device emits a second acoustic signal corresponding to the electrical signal comprising the second predefined frequency.

A twentieth aspect A20 includes the method of the nineteenth aspect A19, further comprising: in response to determining the presence of laser coherence effects, selecting a second amplitude for generation by the signal generator, wherein the second amplitude is different than the amplitude; and causing the signal generator to generate an electrical signal comprising the second amplitude such that the acoustic device emits a third acoustic signal corresponding to the electrical signal comprising the second amplitude.

A twenty-first aspect A21 includes the method of any of the fourteenth to twentieth aspects A14-A20, wherein the one or more optical elements of the optical system are configured within an enclosure and the acoustic generating device is positioned outside the enclosure.

A twenty-second aspect A22 includes the method of any of the fourteenth to twenty-first aspects A14-A21, wherein the one or more optical elements of the optical system are configured within an enclosure and the acoustic generating device is positioned within the enclosure.

A twenty-third aspect A23 includes the method of any of the fourteenth to twenty-second aspects A14-A22, wherein the optical system is an interferometric measurement system.

A twenty-fourth aspect A24 includes the method of any of the fourteenth to twenty-third aspects A14-A23, wherein the optical system is a projection device.

A twenty-fifth aspect A25 includes the method of any of the fourteenth to twenty-fourth aspects A14-A24, wherein the acoustic device is capable of being positioned at more than one distance from the one or more optical elements of the optical system.

A twenty-sixth aspect A26 includes the method of any of the fourteenth to twenty-fifth aspects A14-A25, wherein the one or more optical elements comprises at least one of a prism, a beam splitter, a lens, a mirror, a diffuser, a diffractive grating or optical fiber.

In a twenty-seventh aspect A27, a system includes an optical system comprising a laser light source and an optical element, the laser light source producing a laser beam, the optical element directing the laser beam within the optical system, and an acoustic device remotely coupled to the optical element, the acoustic device configured to emit an acoustic signal, the acoustic signal configured to induce a vibration in the optical element, the vibration having a frequency and an amplitude sufficient to reduce a laser coherence effect of the optical system.

A twenty-eighth aspect A28 includes the system of the twenty-seventh aspect A27, wherein the optical element is an optical element of the laser light source.

A twenty-ninth aspect A29 includes the system of the twenty-seventh aspect A27, wherein the optical element is a mirror, a prism, a lens, a diffuser, a beam-splitter, a diffractive grating or optical fiber.

A thirtieth aspect A30 includes the system of any one of the twenty-seventh to twenty-ninth aspects A27-A29, wherein the optical system further comprises a second optical element, the second optical element further directing the laser beam within the optical system

A thirty-first aspect A31 includes the system the thirtieth aspect A30, wherein the acoustic device is configured to emit a second acoustic signal, the second acoustic signal configured to induce a second vibration in the second optical element, the second vibration having a second frequency and a second amplitude sufficient to further reduce the laser coherence effect of the optical system.

A thirty-second aspect A32 includes the system the thirtieth aspect A30, wherein the optical system further comprises a second acoustic device, the second acoustic device remotely coupled to the second optical element and configured to emit a second acoustic signal, the second acoustic signal configured to induce a second vibration in the second optical element, the second vibration having a second frequency and a second amplitude sufficient to further reduce the laser coherence effect of the optical system.

A thirty-third aspect A33 includes the system of any one of the twenty-seventh to thirty-second aspects A27-A32, further comprising a housing, the housing enclosing the optical element, the acoustic device lacking direct contact with the housing.

A thirty-fourth aspect A34 includes the system of any one of the twenty-seventh to thirty-third aspects A27-A33, wherein the frequency of the vibration is a resonant frequency of the optical element.

A thirty-fifth aspect A35 includes the system of any one of the twenty-seventh to thirty-fourth aspects A27-A34, wherein the laser coherence effect is speckle.

A thirty-sixth aspect A36 includes the system of any one of the twenty-seventh to thirty-fifth aspects A27-A35, wherein the optical system comprises an interferometer.

A thirty-seventh aspect A37 includes the system of any one of the twenty-seventh to thirty-sixth aspects A27-A36, further comprising an electrical signal generator electrically coupled to the acoustic device, the electrical signal generator configured to deliver an electrical signal to the acoustic device, the acoustic device configured to convert the electrical signal to the acoustic signal.

In a thirty-eighth aspect A38 a method includes directing a laser beam to an optical element of an optical system, the optical system exhibiting a laser coherence effect, producing an acoustic signal from an acoustic device remotely coupled to the optical element, and directing the acoustic signal to the optical element, the acoustic signal inducing a vibration in the optical element, the vibration having a frequency and an amplitude sufficient to reduce the laser coherence effect.

A thirty-ninth aspect A39 includes a method of the thirty-eighth A38, wherein the optical element is an optical element of a laser light source configured for generating the laser beam.

A fortieth aspect A40 includes the method of the thirty-eighth or thirty-ninth aspect A38 or A39, wherein the directing laser beam comprises reflecting the laser beam with the optical element.

A forty-first aspect A41 includes the method of any one of the thirty-eighth to fortieth aspects A38-A40, wherein the producing acoustic signal comprises generating an electrical signal from a signal generator electrically coupled to the acoustic device and delivering the electrical signal to the acoustic device, the acoustic device converting the electrical signal into the acoustic signal.

A forty-second aspect A42 includes the method of any one of the thirty-eighth to forty-first aspects A38-A41, wherein the frequency of the vibration is a resonant frequency of the optical element.

A forty-third aspect A43 includes the method of any one of the thirty-eighth to forty-second aspects A38-A42, further comprising directing the laser beam to a second optical element of the optical system, and directing a second acoustic signal from the acoustic device to the second optical element, the second acoustic signal inducing a second vibration in the second optical element, the second vibration having a frequency and an amplitude sufficient to further reduce the laser coherence effect.

A forty-fourth aspect A44 includes the method of any one of the thirty-eighth to forty-third aspects A38-A43, further comprising directing the laser beam to a second optical element of the optical system, and directing a second acoustic signal from a second acoustic device to the second optical element, the second acoustic device remotely coupled to the second optical element, the second acoustic signal inducing a second vibration in the second optical element, the second vibration having a frequency and an amplitude sufficient to further reduce the laser coherence effect.

A forty-fifth aspect A45 includes the method of any one of the thirty-eighth to forty-fourth aspects A38-A44, wherein the laser coherence effect is speckle.

A forty-sixth aspect A46 includes the method of any one of the thirty-eighth to forty-fifth aspects A38-A45, wherein the optical system is an interferometer.

A forty-seventh aspect A47 includes the method of any one of the thirty-eighth to forty-sixth aspects A38-A46, further comprising, before directing the acoustic signal to the optical element, detecting the laser coherence effect.

A forty-eighth aspect A48 includes the method of any one of the thirty-eighth to forty-seventh aspects A38-A47, further comprising detecting the reduced laser coherence effect.

A forty-ninth aspect A49 includes the method of the forty-eighth aspect A48, further comprising modifying a frequency or an amplitude of the acoustic signal and directing the modified acoustic signal to the optical element, the modified acoustic signal inducing a modified vibration in the optical element, the modified vibration further reducing the reduced laser coherence effect.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and are not intended to limit the subject matter defined by the claims. The following detailed description of the illustrative embodiments can be understood when read in conjunction with the following drawings, where like structure is indicated with like reference numerals and in which:

FIG. 1 schematically depicts an example optical system as an illustrative interferometric measurement system, according to one or more embodiments shown and described herein;

FIG. 2 schematically depicts the example optical system of FIG. 1 having an acoustic device configured to reduce laser coherence effects, according to one or more embodiments shown and described herein;

FIG. 3 schematically depicts a computing system for interfacing with and configuring the optical system and the acoustic device to reduce laser coherence effects, according to one or more embodiments shown and described herein;

FIG. 4 depicts a flow diagram of an illustrative method for reducing laser coherence effects, according to one or more embodiments shown and described herein; and

FIG. 5 depicts a plot of illustrative electrical signals generated by the signal generator for reducing laser coherence effects, according to one or more embodiments shown and described herein.

### DETAILED DESCRIPTION

The present disclosure is provided as an enabling teaching and can be understood more readily by reference to the following description, drawings, examples, and claims. To this end, those skilled in the relevant art will recognize and appreciate that many changes can be made to the various aspects of the embodiments described herein, while still obtaining the beneficial results. It will also be apparent that some of the desired benefits of the present embodiments can be obtained by selecting some of the features without utilizing other features. Accordingly, those who work in the art will recognize that many modifications and adaptations are possible and can even be desirable in certain circumstances and are a part of the present disclosure. Therefore, it is to be understood that this disclosure is not limited to the specific compositions, articles, devices, and methods disclosed unless otherwise specified. It is also to be understood that the terminology used herein is for the purposes of describing particular aspects only and is not intended to be limiting.

In this specification and in the claims that follow, reference will be made to a number of terms which shall be defined to have the following meanings:

“Include,” “includes,” “including”, or like terms means encompassing but not limited to, that is, inclusive and not exclusive.

The indefinite article “a” or “an” and its corresponding definite article “the” as used herein means at least one, or one or more, unless specified otherwise.

Directional terms as used herein—for example up, down, right, left, front, back, top, bottom—are made only with reference to the figures as drawn and the coordinate axis provided therewith and are not intended to imply absolute orientation.

As used herein, “comprising” is an open-ended transitional phrase. A list of elements following the transitional phrase “comprising” is a non-exclusive list, such that elements in addition to those specifically recited in the list may also be present.

The term “wherein” is used as an open-ended transitional phrase, to introduce a recitation of a series of characteristics of the structure.

The terms “comprising,” and “comprises,” e.g., “A comprises B,” is intended to include as a special case the concept of “consisting,” as in “A consists of B.”

As used herein, contact refers to direct contact or indirect contact. Direct contact refers to contact in the absence of an intervening material and indirect contact refers to contact through one or more intervening materials. The term “intervening material” refers to a solid or liquid medium. Elements in direct contact touch each other. Elements in indirect contact do not touch each other, but do touch an intervening material or one of a series of intervening materials that continuously fills the space between the elements. Elements in contact may be rigidly or non-rigidly (flexibly) joined. Contacting refers to placing two elements in direct or indirect contact. Elements in direct (indirect) contact may be said to directly (indirectly) contact each other.

The present disclosure relates to systems and methods for reducing problematic laser coherence effects such as speckle and spurious fringes in optical systems. Laser coherence effects can be mitigated by vibrating one or more optical elements in an optical system. Vibration of optical elements at a sufficiently high frequency reduces distortions in images and optical signals caused by laser coherence effects. Customary strategies for effecting vibration are based on direct coupling of a vibration-inducing device (e.g. speaker, piezoelectric device, actuator or MEMS device) to an optical element. Direct coupling entails placing the vibration-inducing device in direct contact with the optical element. A directly coupled vibration-inducing device induces vibrations in an optical element by applying a force to the optical element. The force acts through the direct contact between the directly coupled vibration-inducing device and the optical element to move the optical element. The force acts through a rigid or flexible physical connection that defines the direct or indirect contact between the directly coupled vibration-inducing device and the optical element. The use of directly coupled vibration-inducing devices to mitigate laser coherence effects has been successfully employed in many applications but is disadvantageous or inconvenient in many applications due to, for example, size and space limitations of the optical system or optical elements within the optical system. There is a need for devices and methods for mitigating laser coherence effects that do not rely on directly coupled vibration-inducing devices.

The present disclosure describes techniques for mitigating laser coherence effects in optical systems by inducing vibrations in one or more optical elements without direct coupling of a vibration-inducing device. Vibrations are induced in an optical element without applying mechanical force through or by direct contact between a vibration-inducing device and the optical element. Instead of direct coupling, the vibration-inducing device is acoustically coupled to the optical element. Acoustic coupling is a mechanism for inducing vibration in an optical element that relies on sound waves. An acoustic device produces sound waves that propagate through a gas medium to the optical element to induce vibrations in the optical element. The frequency of the acoustic waves controls the frequency of vibrations in the optical element, which in turn controls the degree to which laser coherence effects are mitigated. The gas medium is typically air, but can be any gas. The force used to induce vibrations in the optical element is not mediated by direct contact of the optical element to the vibration-inducing device, but rather is mediated by sound waves propagating through a gas medium that are produced by an acoustic device lacking direct contact with the optical element. In one embodiment, the acoustic device lacks direct and indirect contact with the optical element. In another embodiment, the acoustic device lacks direct contact with an optical element and is in direct or indirect contact with the optical system (such as, for example, when the acoustic device and optical element lack direct contact, but are connected to a common chassis or housing of the optical system, which is referred to herein as indirect contact). In still another embodiment, the acoustic device lacks direct and indirect contact with an optical element and lacks direct contact with the optical system. In a further embodiment, the acoustic device lacks direct and indirect contact with an optical element and lacks direct and indirect contact with the optical system. An acoustic device lacking direct contact with an optical element in which it induces vibrations is referred to as “remote” or “remotely coupled”.

The techniques described herein induce vibrations in one or more optical elements of an optical system using acoustic (sound) waves and the disclosure demonstrates that vibrations induced by acoustic waves produced by a remote acoustic device reduce laser coherence effects present within the optical system. In particular, it was discovered that through the use of acoustic waves, an acoustic device can be freely positioned at a distance (i.e. remotely coupled; that is, remotely positioned without direct coupling) from the optical system and/or from the particular optical elements in which vibrations are intended to be induced while still acting to reduce laser coherence effects.

Elimination of direct coupling of vibration-inducing devices to optical elements provides greater flexibility in the design of optical systems. For example, when inducing vibrations remotely with acoustic waves, optical elements of an optical system may be preconfigured, structurally supported or positioned in ways that would not be possible with a directly coupled vibration-inducing device due to location, size, and/or accessibility constraints of the optical element within the optical system. A remotely coupled acoustic device also avoids damage to sensitive coatings on surfaces of optical elements that might arise through direct coupling of a vibration-inducing device. For example, it may not be advantageous to directly couple a vibration-inducing device to an optical element having a specialized coating or film layer because the means of attachment (e.g. an adhesive or physical connection) may degrade or interfere with the coating or film layer.

Additionally, as stated above, some optical elements of an optical system may be preconfigured in a location within the optical system that is not conducive to the attachment of a directly-coupled vibration inducing device. For example, if the optical element is located in very close proximity to other optical elements or to the chassis of the optical system, it may not be physically possible to incorporate a directly coupled vibration-inducing device. In some instances, an optical element may be too small to directly couple with a vibration-inducing device and/or the optical element may be inaccessible to the installation of a directly coupled vibration-inducing device, for example, other components of optical system may need to be disassembled and removed to access the optical element that is intended to be vibrated with a directly coupled vibration-inducing device. However, the present embodiments provide a system and method of vibrating an optical element remotely, that is, from a distance without direct contact of a vibration-inducing device to the optical element.

In some instances, inducing vibrations in more than one optical element of an optical system may be required to mitigate laser coherence effects. In such instances, embodiments of the present disclosure may include one or more acoustic devices emitting one or more acoustic signals tuned to cause multiple optical elements to vibrate, thereby reducing laser coherence effects within the optical system. In one embodiment, a remotely coupled acoustic device induces vibrations in one optical element. In another embodiment, a remotely coupled acoustic device induces vibrations in a plurality of optical elements. In still another embodiment, a plurality of remotely coupled acoustic devices induces vibrations in an optical element. In a further embodiment, a plurality of remotely coupled acoustic devices induces vibrations in a plurality of optical elements.

Furthermore, the acoustic device of embodiments of the present disclosure may be tunable such that the frequency of the acoustic signal is varied. There are several reasons why the frequency of the acoustic signal may need to be adjusted. For example, but without limitation, variations in the construction of an optical system may vary slightly from unit to unit thereby affecting the frequency at which an optical element may resonate. As another example, environmental factors such as temperature and/or humidity may have adverse effects on the acoustic signal emitted by the acoustic device, thereby requiring the acoustic signal to be adjusted to account for temperature and/or humidity. For example, humidity can cause attenuation of the acoustic signal, therefore an adjustment in amplitude of the acoustic signal may be needed to account for the attenuation of the acoustic signal as it passes through a humid environment. As such, embodiments described herein will also include systems and methods for tuning the frequency and/or amplitude of the acoustic signal.

It is contemplated that the systems and methods described herein may be implemented as an add-on to an existing optical system or may be designed into the structure and operation of an optical system. For example, the acoustic device, supporting components and methods for reducing laser coherence effects may be added to an off-the-shelf optical system such as an interferometer measurement system or a laser projector to reduce laser coherence effects within the off-the-shelf optical system. In other examples, an optical system may be designed to include an acoustic device and supporting components within the optical system, rather than as an add-on system.

Embodiments of the present disclosure and, in particular, systems and methods for reducing laser coherence effects using acoustic signals will now be described. The following will now describe the systems and methods in more detail with reference to the drawings and where like numbers refer to like structures.

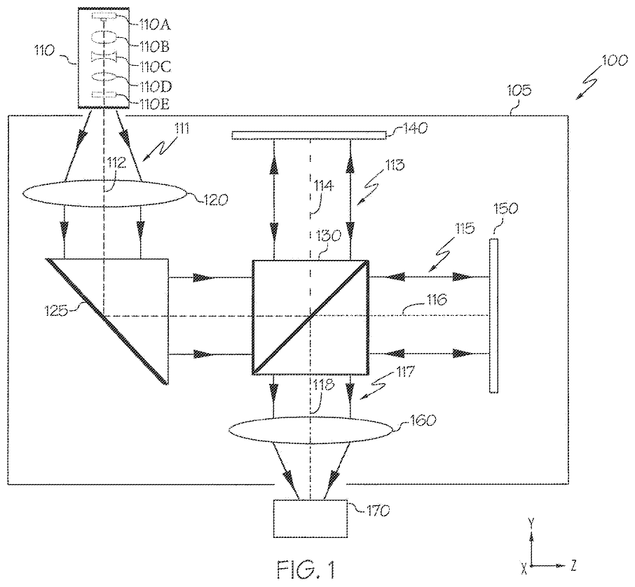

Referring to FIG. 1, an example optical system 100 is illustrated as an interferometric measurement system, according to one or more embodiments shown and described herein. In particular, FIG. 1 illustratively depicts a Michelson interferometer, more specifically, a Twyman-Green interferometer. However, the depicted interferometer is only one example of an interferometer configuration. In some embodiments, other interferometer configurations such as a Fabry-Perot interferometer, a Fizeau interferometer (a variation of the Fabry-Perot), a Mach-Zehnder interferometer, and a Sagnac interferometer are implemented in place of the Michelson interferometer depicted in FIG. 1. That is, FIG. 1 and the description of the embodiments for reducing laser coherence effects using acoustic signals as discussed with reference to the Michelson interferometer, however, it is understood that the systems and methods described herein may be applied in other interferometer configurations.

An interferometric measurement system is only one example of an optical system 100 which may implement the systems and methods described herein to improve the quality and performance of the optical system 100. Although the disclosure generally refers to an interferometric measurement system as the optical system 100 and the optical components therein, it is understood that projection systems, illumination systems, imaging systems, and other optical systems implementing a laser light source 110 and optical elements may benefit from the systems and methods described herein to reduce laser coherence effects.

In some embodiments, the optical elements of the optical system 100 may be housed and mounted within an enclosure 105. However, this is not a requirement as in some instances the optical system 100 may only be partially housed in an enclosure 105 or not housed within an enclosure 105 at all.

An interferometric measurement system is a very precise instrument designed to measure objects with high levels of accuracy. In general, interferometry involves taking a beam of light such as a laser beam 111 produced by a laser light source 110 or another type of electromagnetic radiation and directing the laser beam 111, optionally, through one or more optical elements such as a lens 120 and/or a prism 125. The laser beam 111 produced by the laser light source 110 travels along a beam path 112. The laser light source 110, which is an element of the optical system 100, may include one or more optical elements. For example, a laser light source 110 may include a laser diode 110A. The laser diode 110A is a device capable of converting electrical energy into light. For example, the laser diode 110A may be a semiconductor device having a diode that is fed electrical current generates lasing conditions at the diode's junction. The laser light source 110 may further include one or more lenses and/or filters 110B, 110C, 110D, 110E to generate a collimated laser beam 111. For example, but without limitation, the laser light source 110 may generate light using a laser diode 110A which impinges a focusing lens 110B, an expanding lens 110C, a collimating lens 110D, and/or a filter 110E each of which may be configured within the beam path 112 of the laser light source 110. However, this is only one example. The laser light source 110 may include one or more combinations of optical elements. As discussed herein in more detail one or more of the optical elements of the laser light source 110 may be vibrated to reduce and/or eliminate laser coherence effects.

The laser beam 111 produced by the laser light source 110 travels along the beam path 112 and optionally impinges one or more optical elements including the prism 125, which may redirect the laser beam 111 into a beam-splitter 130. The beam-splitter 130 splits the laser beam 111 into two identical beams, a measurement beam 113 and a reference beam 115, that travel two different beam paths, a measurement beam path 114 and a reference beam path 116, respectively. The beam-splitter 130 may also be referred to as a half-transparent mirror or a half-mirror. For example, the beam-splitter 130 may be a piece of glass whose surface is thinly coated with silver such that when light is shined on the beam-splitter 130, half the light passes straight through and half is reflected at an angle.

The measurement beam 113 shines onto an object surface 140 which is to be measured and reflected back to the beam-splitter 130 along the measurement beam path 114. The reference beam 115 traveling along the reference beam path 116 shines upon a mirror 150 and is reflected back to the beam splitter 130 along the reference beam path 115.

At least one of the measurement beam 113 or the reference beam 115 travels an extra distance (or in some other slightly different way) with respect to the other beam, so it gets slightly out of step (out of phase). Upon return to the beam-splitter 130, the measurement beam 113 and the reference beam 115 are directed to a screen or detector device 170. FIG. 1 depicts this as return beam 117 which travels along return beam path 118. In some embodiments, the return beam 117 may pass through one or more optical elements such as a lens 160.

When the two light beams meet up at the screen or detector device 170, they overlap and interfere, and the phase difference between them creates a pattern of light and dark areas (in other words, a set of interference fringes). The light areas are places where the two beams have added together (i.e., constructively) and become brighter; the dark areas are places where the beams have subtracted from one another (i.e., destructively). The exact pattern of interference depends on the different way or the extra distance that one of the beams has traveled. By inspecting and measuring the fringes, a calculation using methods known in the art can be performed to determine a measurement that is desired, such as surface smoothness, an edge contour, or other measurements with great accuracy.

In some instances, instead of the interference fringes falling on a simple screen, they are often directed into a detector device 170 such as a camera to produce a permanent image called an interferogram. That is, the interferogram may be made by a detector device 170, for example, a CCD image sensor used in digital cameras that converts the pattern of fluctuating optical interference fringes into an electrical signal that can be very easily analyzed with a computing device.

A common issue with interferometric measurement systems, and generally with any optical system that implements a laser light source 110 is the presence of laser coherence effects. Laser coherence effects, which may be more specifically classified or referred to as speckle and/or spurious edges, cause images such as an interferogram to have a grainy appearance or speckled patterns. In general, laser coherence effects such as speckle are a result of the interference of many waves of the same frequency, having different phases and amplitudes, which add together to give a resultant wave whose amplitude, and therefore intensity, varies randomly. When a surface is illuminated by a light wave, according to diffraction theory, each point on an illuminated surface acts as a source of secondary spherical waves. Speckle patterns typically occur in diffuse reflections of monochromatic light such as laser light. However, speckle and other laser coherence effects can be caused by light scattering off of dust or any diffuse reflective surface. Such reflections may occur on materials with non-specular surfaces such as paper, white paint, rough surfaces, or in media with a large number of scattering particles in space, such as airborne dust or in cloudy liquids. The light at any point in the scattered light field is made up of waves which have been scattered from each point on the illuminated surface, for example, an optical element which the light is transmitted through and/or manipulated through impingement of the optical element. If the surface is rough enough to create path-length differences, for example, exceeding one wavelength, giving rise to phase changes greater than 2π, the amplitude, and hence the intensity, of the resultant light varies randomly.

When measuring the smoothness of an object surface 140 with an interferometer, for example, at least one interference pattern is generated from the beam (e.g., the measurement beam 113) impinging and being reflected from the object surface 140 being measured. After being perturbed by interaction with the sample under test, the measurement beam 113 is recombined with the reference beam 115 to create an interference pattern (e.g., an interferogram) which can then be interpreted. However, when laser coherence effects are present in the beam used within the optical system 100, for example, in an interferometer, the laser coherence effects increases the level of noise within the measurement beam 113, the reference beam 115, the return beam 117, and ultimately the interference pattern (e.g., an interferogram), which makes interpretation of the results difficult, inaccurate, and in some instance impossible. Therefore, it is advantageous to reduce and/or remove the laser coherence effects within the beam having the undesired laser coherence effects such as the laser beam 111. The present disclosure focuses on reducing and/or removing the undesired and/or problematic laser coherence effects, such as speckle or diffraction fringes seen at the edges which do not result from the impingement and reflection of the measurement beam 113 with the object surface 140.

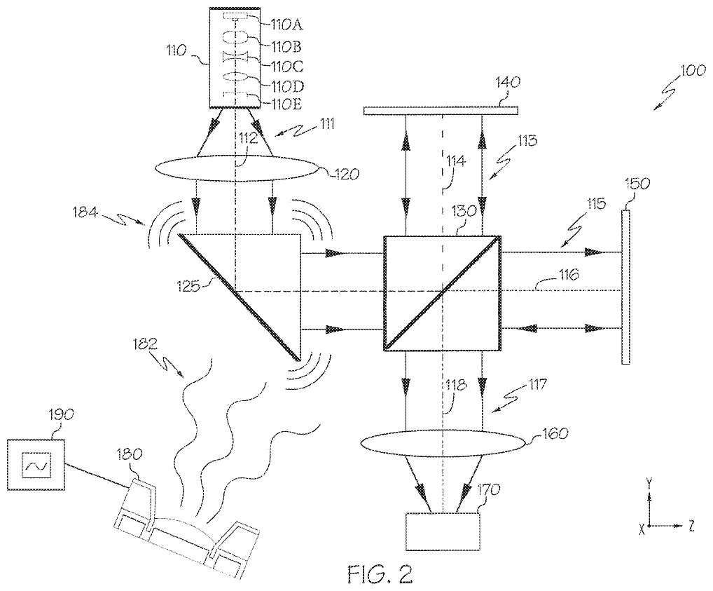

In some embodiments, by vibrating one or more optical elements and/or the laser light source 110 or components thereof, the vibrations disturb the temporal coherence of the laser beam 111, thereby reducing and/or removing the undesired and/or problematic laser coherence effects. Furthermore, in some embodiments, the laser beam 111 is directed into a single mode fiber from the laser light source 110 so changes to the laser beam may be prevented or reduced until exiting the single mode fiber and, optionally, subsequently entering the interferometer or other optical system. Moreover, the acoustic device 180 (FIG. 2) may be positioned so that it is targeting the laser light source 110 such that acoustic signals 182 (FIG. 2) from the acoustic device 180 avoid disturbing the optical elements of the interferometer and the sample (e.g. the object surface 140). In such embodiments, any optical element causing laser coherence effects (or introducing undesired interference) may be vibrated, other than the sample (e.g., the object surface 140), measurement components of the interferometer, and/or the beam-splitter 130. That is, in some instances, vibration of a component within a measurement system such as an interferometer may cause optical elements of the measurement system having predefined relationships to negatively impact the measurement performance. Therefore, the frequency and/or amplitude at which the acoustic signal is generated to project may be tuned and selectively directed towards the one or more optical elements of the optical system including but not limited to the optical elements (e.g., the lens and/or filters 110B-110E) of the laser light source 110 to vibrate. However this is only one example, as any optical element configured for directing the laser beam from the laser light source and/or the optical system (e.g., an interferometer or projection device) may be selectively vibrated by tuning to the acoustic signal 182 to a frequency and amplitude that induces vibration. The vibrations induced in the system may be in the laser, which has the effect of disturbing the temporal coherence and/or spectral coherence of the laser beam 111.

Turning to FIG. 2, the optical system 100 depicted as described with reference to FIG. 1 is illustrated as well as a remotely coupled acoustic device 180 and a signal generator 190 to reduce laser coherence effects within the optical system 100. In embodiments, the acoustic device 180 is electrically coupled to a signal generator 190. The signal generator 190 is configured to generate an electrical signal comprising a predefined frequency and a predefined amplitude. The electrical signal is transmitted to the acoustic device 180 such that the acoustic device 180 converts the electrical signal into an acoustic signal 182. The frequency and amplitude of the acoustic signal 182 is controlled by the predefined frequency and predefined amplitude of the electrical signal. In the embodiment shown in FIG. 2, the acoustic signal 182 causes the prism 125 to vibrate as illustrated by the vibration waves 184. Note that acoustic device 180 lacks direct contact with prism 125. It is further noted that although FIG. 2 depicts the acoustic signal 182 causing the prism 125 to vibrate, other optical elements within the laser system (e.g., laser light source 110 or optical elements within laser light source 110, the lens 120, or other optical elements which direct the laser beam 111) and/or the one or more optical elements of the optical system 100 may be vibrated to reduce laser coherence effects. Although the prism 125 is depicted as the optical element being vibrated, other optical elements that may be vibrated include, but are not limited to, a lens, a mirror, a diffuser, a diffractive grating or other diffractive surface, or optical fiber, or the like.

Achieving and maintaining a coherent laser light source, in some embodiments, improves the quality of the measurement or projection since the light utilized by the system either does not include laser coherence effects or they are reduced through the systems and methods described herein. As such, any optical elements in the beam path may be induced to vibrate by an acoustic signal 182 generated by an acoustic device 180 in order to reduce or eliminate laser coherence effects in the light that enters and is utilized by the optical system 100.

Still referring to FIG. 2, the acoustic device 180 may be any device capable of converting an electrical signal into an acoustic signal 182. For example, the acoustic device 180 may be a speaker such as a loud speaker, a piezo-electric device, or the like. The acoustic device 180 is positioned at a distance from the one or more optical elements of the optical system 100. The acoustic device 180 may be configured within an enclosure 105 (FIG. 1) housing the optical system 100 or may be positioned outside the enclosure 105. In some embodiments, the acoustic device 180 may be repositionable with respect to the optical system 100 so that acoustic signals 182 generated by the acoustic device 180 may be more efficiently acoustically coupled with the one or more optical elements intended to be vibrated. That is, repositioning of the acoustic device 180 permits preferential transmission of the acoustic signal 182 to selected optical elements of optical system 100.

The electrical signal generated by the signal generator 190 may include a frequency of one to 999 hertz (Hz), 1 kilohertz (kHz) to 999 kilohertz, 1 megahertz (MHz) to 999 megahertz, or any other frequency determined to cause one or more of the optical elements of the optical system to vibrate such that laser coherence effects within the optical system 100 are reduced when the corresponding acoustic signal 182 is emitted by the acoustic device 180. For example, the frequency may optionally be a frequency in the range of 700 hertz to 900 hertz, optionally about 800 hertz, 810 hertz, 820 hertz, 830 hertz, 840 hertz, 850 hertz, 860 hertz, 870 hertz, 880 hertz, or 890 hertz. The electrical signal generated by the signal generator 190 may include an amplitude of a few hundred millivolts (mV) to a few volts (V). For example, the amplitude may be 100 mV to 3.0 V, or any value therebetween. The amplitude of the electrical signal may be adjusted to increase or decrease the intensity of a vibration and/or to account for attenuation of the acoustic signal 182.

However, it is not an object of the present disclosure to merely cause vibration of one or more optical elements, but rather to implement selective vibration of one or more optical elements such that laser coherence effects are reduced or eliminated. For example, to achieve selective vibration of one or more optical elements, a tuning process and/or a simulation process such as a finite element analysis may be performed to determine an optimal frequency or range of frequencies that may result in reduced laser coherence effects.

For example, the optical system may be modeled in a computer system and a finite element analysis may be used to determine the natural frequency and corresponding resonant frequencies of one or more of the optical components of the optical system as they are configured and supported with the other components of the optical system 100. In some embodiments, the signal generator 190 may generate an electrical signal having a resonant frequency corresponding to the natural frequency of one or more of the optical elements thereby selectively causing specific, pre-selected optical elements to vibrate.

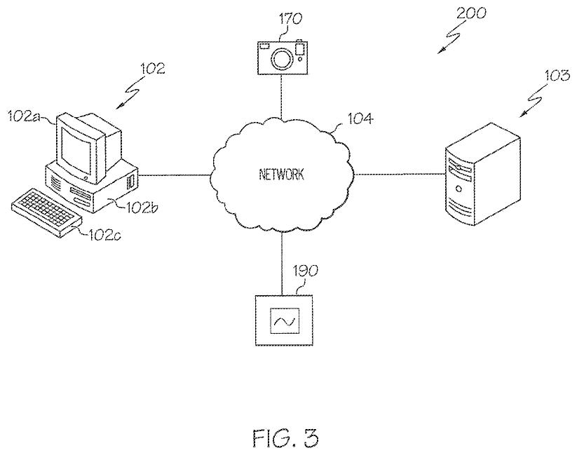

Referring briefly to FIG. 3, some embodiments include a computing system 200 communicatively coupled to the optical system 100 for configuring the signal generator 190 to reduce laser coherence effects within the optical system 100. The computing system 200 may include a computing device 102 communicatively coupled to the signal generator 190, the detector device 170, and/or a server 103. The computing device 102, the signal generator 190, the detector device 170, and/or the server 103 may be directly coupled or coupled through a network 104. The network 104 may include a wide area network, such as the internet, a local area network (LAN), a mobile communications network, a public service telephone network (PSTN) and/or other network.

The computing device 102 may include a display 102a, a processing unit 102b and an input device 102c, each of which may be communicatively coupled together and/or to the network 104. The computing device 102 may be used to interface with a user who may adjust and/or configure the signal generator to reduce laser coherence effects within the optical system and/or perform a finite element analysis of the optical system. Additionally, included in FIG. 3 is the server 103. The server 103 may be utilized to carry out specific tasks such as simulations, analysis of detector data to determine the presence of laser coherence effects in the optical system or the like which may require dedicated processing resources and/or store signal configurations for the signal generator based on specific component configurations of the optical system.

It should be understood that the computing device 102 and the server 103 are depicted as a personal computer and a server device, these are merely examples. More specifically, any type of computing device (e.g., mobile computing device, personal computer, server, phone, and the like) may be utilized for any of these components. Additionally, while each of these computing devices is illustrated in FIG. 3 as a single piece of hardware, this is also an example. More specifically, each of the computing device 102 and the server 103 may represent a plurality of computers, servers, databases, and the like. For example, each of the user computing device 102 and the server 103 may form a distributed or grid-computing framework for implementing the methods described herein.

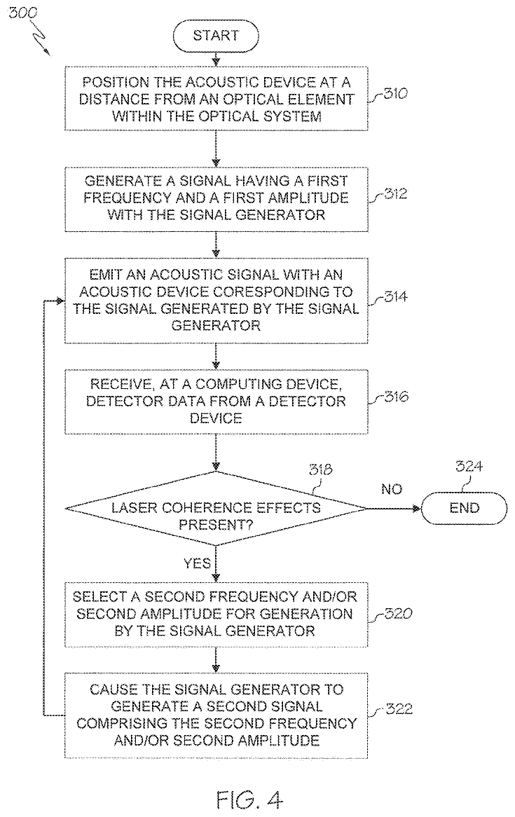

Referring now to FIG. 4, a flow diagram 300 depicting an illustrative method implemented by the optical system 100 (e.g., as depicted and described with reference to FIG. 2) and/or the computing system 200 (e.g., as depicted and described with reference to FIG. 3) is depicted. At block 310, the acoustic device 180 (e.g., as depicted and described with reference to FIG. 2) is positioned at a distance from an optical element such as the prism 125 (e.g., positioned remotely as depicted and described with reference to FIG. 2). As described above, the acoustic device 180 is positioned at a distance from the one or more optical elements so that the acoustic device may cause one or more of the optical elements to vibrate thereby reducing the laser coherence effects within the optical system 100. At block 312, a signal generator 190 (e.g., as depicted and described with reference to FIG. 2) generates an electrical signal comprising a predefined frequency and a predefined amplitude to control output of an acoustic signal 182 by an acoustic device 180 electrically coupled to the signal generator 190. At block 314, an acoustic device 180 emits an acoustic signal 182 (e.g., as depicted and described with reference to FIG. 2) corresponding to the electrical signal generated by the signal generator 190 at block 312. The acoustic signal 182 may be a resonant frequency of one or more optical elements. By using the resonant frequency, one or more optical elements may be selectively vibrated.

In some embodiments, for example, during manufacture of the optical system 100 and/or during initial calibration and setup it may be necessary to tune the electrical signal generated by the signal generator 190. At block 316, a computing device 102 may be communicatively coupled to the signal generator 190 and the detector device 170 (e.g., as depicted and described with reference to FIG. 3). The detector device 170 may be a permanent component of the optical system 100 or may be selectively installed with the optical system 100 for tuning the signal generator 190 (e.g., as depicted and described with reference to FIG. 3). Still referring to block 316, the computing device 102 receives detector data from the detector device 170 (e.g., as depicted and described with reference to FIGS. 2 and 3). The detector data may be represented as an interferogram. The computing device, at block 318, analyzes the detector data and determines whether there are laser coherence effects present in the detector data. The computing device 102 may implement image and or pixel processing techniques that can determine the percent modulation in an array of pixels to determine whether laser coherence effects are present. These techniques may also quantify the determination such that if the percent modulation is greater than a predefined value then a determination is made that laser coherence effects are present and if the percent modulation is below a predefined value then a determination may conclude that the laser coherence effects are not present or at least below an acceptable level.

In embodiments where laser coherence effects are determined to be present at block 318, the computing device 102 advances to block 320 where a second frequency and/or amplitude is selected to adjust the electrical signal being generated by the signal generator 190. The adjustment may be a shift up or down in the frequency value and/or an increase or decrease in the amplitude of the electrical signal to direct output of a second acoustic signal 182 from acoustic device 180. There may be a predefined range of frequencies that will reduce the laser coherence effects of the optical system 100 such that it is a matter of selecting the frequency in the range to maximize the reduction of the laser coherence effects. At block 322, the computing device causes the signal generator 190 to generate the second electrical signal comprising the second frequency and/or the second amplitude. Then, as depicted the process returns to block 314 where then acoustic device 180 emits a second acoustic signal 182 corresponding to the second electrical signal generated by the signal generator 190. For here, the process repeats through blocks 316 and 318. Should the adjustment to the acoustic signal 182 not reduce the laser coherence effects to or below a predefined level such that the laser coherence effects remain present, a further adjustment to the acoustic signal 182 may be made by repeating the process of blocks 320 and 322. However, in instances where the laser coherence effects are determined to be reduced or nonexistent above a predefined level at block 318 by the computing device, then the process of tuning may end at block 324. Upon ending at block 324, the electrical signal values of frequency and amplitude may be stored or written to a memory component of the signal generator such that the signal generator may operate independent of the computing device 102.

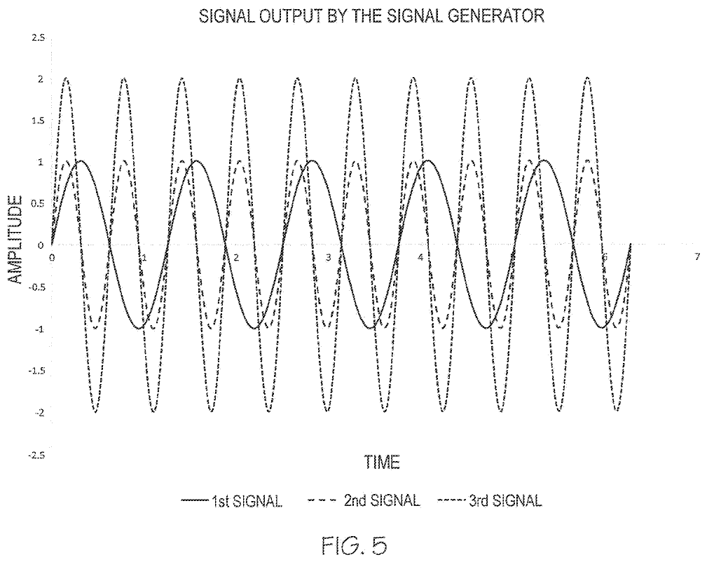

Briefly turning to FIG. 5 a plot illustrating electrical signals having different frequencies and/or amplitudes is depicted. In some embodiments, the signal is a sine wave, however, this is only an example. A first electrical signal may have a first predefined frequency and first predefined amplitude. A second electrical signal, for example, as selected by the computing device in block 320 may have a second predefined frequency that is different than the first predefined frequency, but the amplitude may remain the same as the first electrical signal. Should additional adjustments to the electrical signal be necessary to direct acoustic device 180 to produce an acoustic signal 182 that minimizes laser coherence effects, a third electrical signal or further electrical signal may be formulated. For example, a third electrical signal may maintain the frequency of the prior electrical signal but adjust the amplitude, for example, as depicted by the third electrical signal in FIG. 5, to increase the amplitude. Increasing the amplitude of a signal may account for attenuation effects on the acoustic signal 182 as it is transmitted through the environment and components such as the enclosure 105 (FIG. 1) so that it may reach the one or more optical elements. It should be understood that FIG. 5 only depicts a few example electrical signals having various frequencies and amplitudes. The values of the frequencies and amplitudes depicted are merely illustrated as examples. Specific values may be determined or informed through simulations such as a finite element analysis of the optical system or knowledge of the natural frequency of the optical element that is intended to be vibrated.

It should now be understood that embodiments described herein relate to systems and methods for reducing problematic laser coherence effects such as speckle and spurious fringes from optical systems. As discussed above, the disclosure demonstrates that by inducing vibrations into one or more optical elements of an optical system using acoustic waves delivered by a remotely coupled acoustic device, laser coherence effects present within the optical system can be reduced. In particular, it was discovered that through the use of acoustic waves, an acoustic device could be freely positioned at a distance from the optical system and/or particular optical elements which are desirous to vibrate. Moreover, optical elements of an optical system may be preconfigured and structurally supported such that direct coupling of a vibration-inducing device to the optical element would not be possible due to the location, size, or accessibility of the optical element within the optical system and/or because of the sensitive nature of the optical element to contact with other components.

Additionally, as stated above some optical elements of an optical system may be preconfigured in a location within the optical system that is not conducive to the addition of other components, for example, the optical element is located in very close proximity to components. In some instances, an optical element may be too small to couple with a vibration-inducing device and/or the optical element may be inaccessible to the installation of a vibration-inducing device, for example, other components of optical system may need to be disassembled and removed to access the optical component. Therefore, the present embodiments provide a system and method of inducing vibrations in an optical element from a distance via an acoustic signal produced by a remotely coupled acoustic device.

Furthermore, embodiments of the present disclosure include methods for tuning the acoustic signal emitted by the acoustic device. There are several reasons why the acoustic signal may need to be adjusted. For example, but without limitation, variations in the construction of an optical system may vary thereby affecting the frequency at which an optical element may resonant. As another example, environmental factors such as temperature and/or humidity may have adverse effects on the acoustic signal emitted by the acoustic device, thereby requiring the acoustic signal to be adjusted to account for temperature and/or humidity.

The systems and methods described herein may be implemented as an add-on to an existing optical system or may be designed into the structure and operation of an optical system. For example, the acoustic device and supporting components and methods may be implemented with an off-the shelf optical system such as an interferometer measurement system or a laser projector to reduce laser coherence effects within the optical system. In other examples, an optical system may be designed to include an acoustic device and supporting components within the optical system, rather than as an add-on system.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A system comprising:
an acoustic device;
a signal generator electrically coupled to the acoustic device, wherein the signal generator generates an electrical signal comprising a predefined frequency and a predefined amplitude for output by the acoustic device; and
an optical system comprising a laser light source configured to produce a beam wherein one or more optical elements are disposed along a beam path that impinges or propagates through the one or more optical elements;
wherein the acoustic device is positioned at a distance from the one or more optical elements such that an acoustic signal emitted by the acoustic device causes the one or more optical elements to vibrate such that laser coherence effects of the beam are reduced.

2. The system of claim 1, wherein the one or more optical elements is an optical element of the laser light source.

3. The system of claim 1, wherein the predefined frequency is a resonant frequency of at least one of the one or more optical elements of the optical system.

4. The system of claim 1, further comprising:
a detector positioned within the optical system along the beam path of the beam produced by the laser light source; and
a computing device communicatively coupled to the detector and the signal generator, wherein the computing device is programmed to:
receive detector data from the detector while the acoustic device emits the acoustic signal corresponding to the electrical signal comprising the predefined frequency;
determine whether laser coherence effects are present within the beam based on the detector data captured by the detector;
in response to determining the presence of laser coherence effects, select a second predefined frequency for generation by the signal generator, wherein the second predefined frequency is different than the predefined frequency; and
cause the signal generator to generate an electrical signal comprising the second predefined frequency such that the acoustic device emits a second acoustic signal corresponding to the electrical signal comprising the second predefined frequency.

5. The system of claim 1, wherein the one or more optical elements of the optical system are configured within an enclosure and the acoustic generating device is positioned outside the enclosure.

6. The system of claim 1, wherein the one or more optical elements comprises at least one of a prism, a beam splitter, a lens, a mirror, a diffuser, a diffractive grating or optical fiber.

7. A method comprising:
generating an electrical signal, with a signal generator, comprising a predefined frequency and a predefined amplitude for output by an acoustic device electrically coupled to the signal generator, wherein the acoustic device is positioned a distance from an optical system comprising a laser light source configured to produce a beam wherein one or more optical elements are disposed along a beam path that impinges or propagates through the one or more optical elements; and
emitting, with the acoustic device, an acoustic signal corresponding to the electrical signal received from the signal generator, wherein the acoustic signal causes the one or more optical elements to vibrate such that laser coherence effects of the beam are reduced.

8. The method of claim 7, wherein the one or more optical elements is an optical element of the laser light source.

9. The method of claim 7, wherein the predefined frequency is a resonant frequency of at least one of the one or more optical elements of the optical system.

10. The method of claim 7, further comprising:
receiving, at a computing device, detector data from a detector positioned within the optical system along the beam path of the beam produced by the laser light source, while the acoustic device emits the acoustic signal corresponding to the electrical signal comprising the predefined frequency;
determining whether laser coherence effects are present within the beam based on the detector data captured by the detector;
in response to determining the presence of laser coherence effects, selecting a second predefined frequency for generation by the signal generator, wherein the second predefined frequency is different than the predefined frequency; and
causing the signal generator to generate an electrical signal comprising the second predefined frequency such that the acoustic device emits a second acoustic signal corresponding to the electrical signal comprising the second predefined frequency.

11. The method of claim 7, wherein the one or more optical elements of the optical system are configured within an enclosure and the acoustic generating device is positioned outside the enclosure.

12. The method of claim 7, wherein the one or more optical elements comprises at least one of a prism, a beam splitter, a lens, a mirror, a diffuser, a diffractive grating or optical fiber.

13. A system comprising:
an optical system comprising a laser light source and an optical element, the laser light source producing a laser beam, the optical element directing the laser beam within the optical system; and
an acoustic device remotely coupled to the optical element, the acoustic device configured to emit an acoustic signal, the acoustic signal configured to induce a vibration in the optical element, the vibration having a frequency and an amplitude sufficient to reduce a laser coherence effect of the optical system.

14. The system of claim 13, wherein the optical element is an optical element of the laser light source.

15. The system of claim 13, wherein the optical element is a mirror, a prism, or a beam splitter.

16. The system of claim 13, wherein the optical system further comprises a second optical element, the second optical element further directing the laser beam within the optical system.

17. The system of claim 16, wherein the acoustic device is configured to emit a second acoustic signal, the second acoustic signal configured to induce a second vibration in the second optical element, the second vibration having a second frequency and a second amplitude sufficient to further reduce the laser coherence effect of the optical system.

18. The system of claim 16, wherein the optical system further comprises a second acoustic device, the second acoustic device remotely coupled to the second optical element and configured to emit a second acoustic signal, the second acoustic signal configured to induce a second vibration in the second optical element, the second vibration having a second frequency and a second amplitude sufficient to further reduce the laser coherence effect of the optical system.

19. The system of claim 13, further comprising a housing, the housing enclosing the optical element, the acoustic device lacking direct contact with the housing.

20. The system of claim 13, wherein the frequency of the vibration is a resonant frequency of the optical element.
